(19) United States
(12) Patent Application Publication
(10) Pub. No.: US 2009/0189637 A1
(43) Pub. Date: Jul. 30, 2009

(54) Machine for programming on-board chipsets

(75) Inventors: Chih-Jen Chin, Taipei City (TW); Sheng-Yuan Tsai, Taipei City (TW)

Correspondence Address: CKC & Partners Co. Ltd;12th Fl., Ruttonjee House, 11 Duddell Street, Hong Kong, HK

(73) Assignee: Inventec Corporation

(21) Appl. No.: 12/010,725

(22) Filed: Jan. 29, 2008

(51) Int. Cl. H03K 19/173

(52) U.S. Cl. 326/38

(57) ABSTRACT

The present invention discloses a machine for programming on-board chipsets, wherein the on-board chipsets means that some chipsets are mounted on a circuit board, and the circuit board has a plurality of input pads electrically connected to each chipset individually. The machine comprises a platform, a number of programming modules and an IC programming burner in which the platform faces a surface of the circuit board having the input pads, the programming modules disposed movably on the platform separately extends a number of output pins outwardly so that for connecting electrically an input pad as contacting the input pad, and the IC programming burner electrically connected to each of the programming modules separately distributes a set of programming codes into each programming module when the output pins electrically connect to the input pads.

### BACKGROUND

1. Field of Invention

The present invention relates to a machine for chipset programming. More particularly, the present invention relates to a machine for programming on-board chipsets simultaneously.

2. Description of Related Art

Traditionally, there are two different conditions for a chipset to save programming codes (e.g. firmware) therein. The first one is to place a chipset on an IC burner while the chipset is not mounted on the printed circuit board (PCB) yet and so that the programming codes can be directly burned-in. The second one is to save programming codes to an on-board chipset, that is, a chipset has been mounted on a PCB and the PCB may have more than one on-board chipset.

Since most PCBs contain more than one on-board chipset and each on-board chipset characterizes different functions and formats, when the code programming procedure of the on-board chipsets starts, the circuit board has to be carried through different code programming areas to burn-in different sets of codes into the chipset in sequence, according to the on-board chipset functions and formats.

Therefore, in aspect of mass production, the second type of programming codes into a chipset reflects drawbacks of huge time consumption and production cost in moving the circuit board around the code programming areas, and decreasing utilized area due to the disposed code programming areas.

### SUMMARY

It is therefore an aspect of the present invention to provide a machine for programming on-board chipsets, which enables users to adapt different layout designs of chipsets to program codes simultaneously into those on-board chipsets, so as to cut down in time consumption and production cost of the code programming process.

According to one preferred embodiment of the present invention, a machine for programming on-board chipsets includes a platform, an IC programming burner and a circuit board for processing. The circuit board has a plurality of chipsets and a plurality of input portions. Each input portion respectively corresponds to a chipset and consists of a plurality of input pads electrically connected to the corresponding chipset for transmitting programming codes.

Many programming modules are electrically connected to the IC programming burner, movably disposed on the platform, and separately have a plurality of output pins extending towards the circuit board, wherein each of the output pins corresponds to one of the input pads to electrically connect the corresponding input pad when they are in contact with each other. When the output pins of one programming module are electrically connected the corresponding input pads respectively, the IC programming burner separately distributes a different set of programming codes into each chipset via the output pins and the corresponding input pads, so as to finish the code programming process of the on-board chipset.

It is to be understood that both the foregoing general description and the following detailed description are examples, and are intended to provide further explanation of the invention as claimed.

### BRIEF DESCRIPTION OF THE DRAWINGS

These and other features, aspects and advantages of the present invention will become better understood with regard to the following description, appended claims and accompanying drawings where:

FIG. 1 is a front view of a circuit board of the present invention;

FIG. 2 is a schematic diagram depicting relations to the circuit board, programming modules of a platform and an IC programming burner.

FIG. 3 is a schematic diagram of a positioning mechanism in one preferred embodiment of the present invention; and

FIG. 4 is a schematic diagram of a positioning mechanism in another preferred embodiment of the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

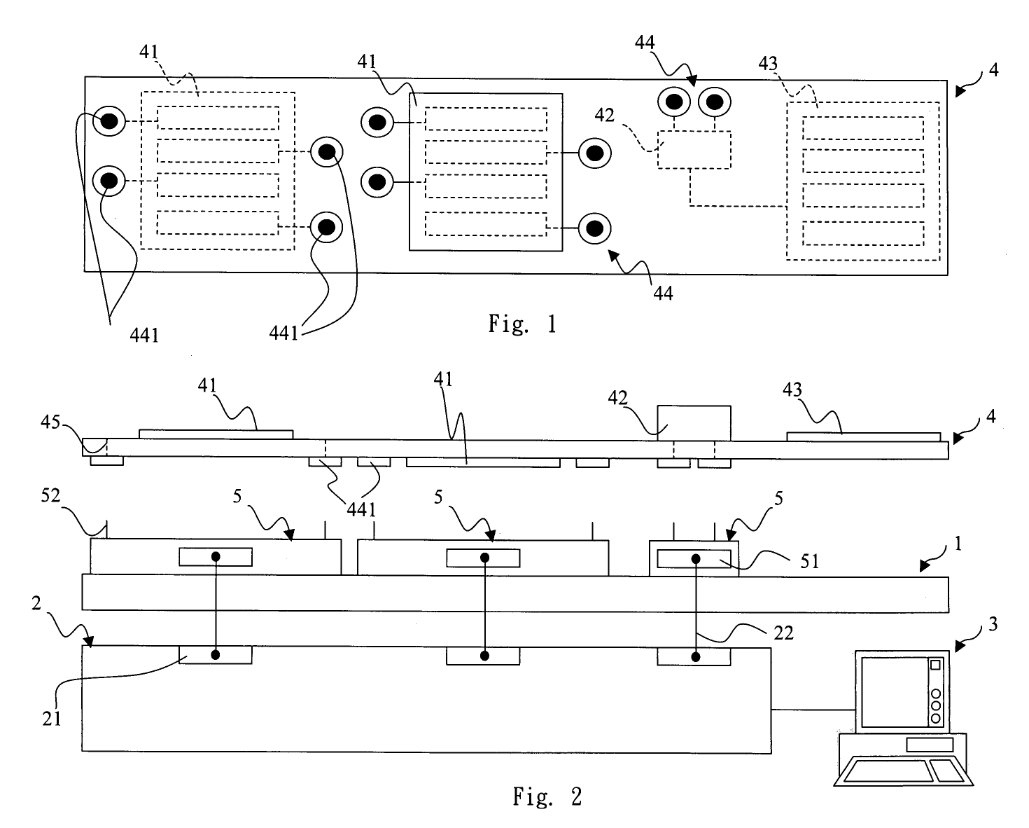

FIG. 1 is a front view of a circuit board of the present invention and FIG. 2 is a schematic diagram depicting relations to the circuit board, programming modules of a platform and an IC programming burner. A machine for programming on-board chipsets in an embodiment of the present invention comprises a platform 1, an IC programming burner 2 electrically connected to a number of programming modules 5, a computer device 3 electrically connected to the IC programming burner 2, and a circuit board 4 whose chipsets need to be programmed, has some on-board chipsets 41, at least one connecting jack 42 and a number of input portions 44 thereon. Each input portion 44 corresponds to either one chipset 41 or one connecting jack 44 and consists of a number of input pads 441 electrically connected to the corresponding chipset 41 or the connecting jack 42.

The input pads 441 of each input portion 44 either are arranged on the circuit board 4 as the same surface as the corresponding chipset 41 or the corresponding connecting jack 42 is arranged on, or the input pads 441 of each input portion 44 may be arranged on the circuit board 4 as the opposite surface as the corresponding chipset 41 or the corresponding connecting jack 42 is arranged on. When the input pads 441 of each input portion 44 are arranged opposite to the corresponding chipset 41 or the corresponding connecting jack 42, these input pads 441 are electrically connected to the corresponding chipset 41 or the corresponding connecting jack 42 by penetrating through the circuit board 4 via cords for transmitting programming codes.

Each of the connecting jacks 42 further connects one or more other chipsets 43 that are essentially the same as the forgoing chipset 41. The only difference between the chipsets 41 and other chipsets 43 is the other chipsets 43 receive the programming codes from the corresponding input pads 441 via the connecting jacks 42, not from the corresponding input pads 441 directly as the chipsets 41 do. Thus, the connecting jacks 42 are provided for another way to transmit programming codes to the chipset 43.

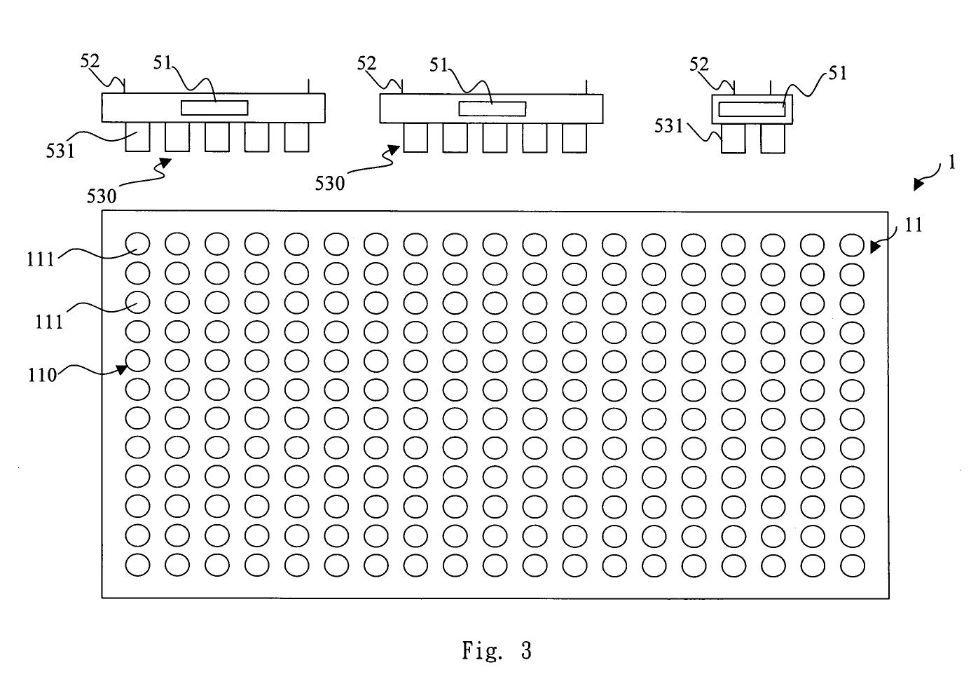

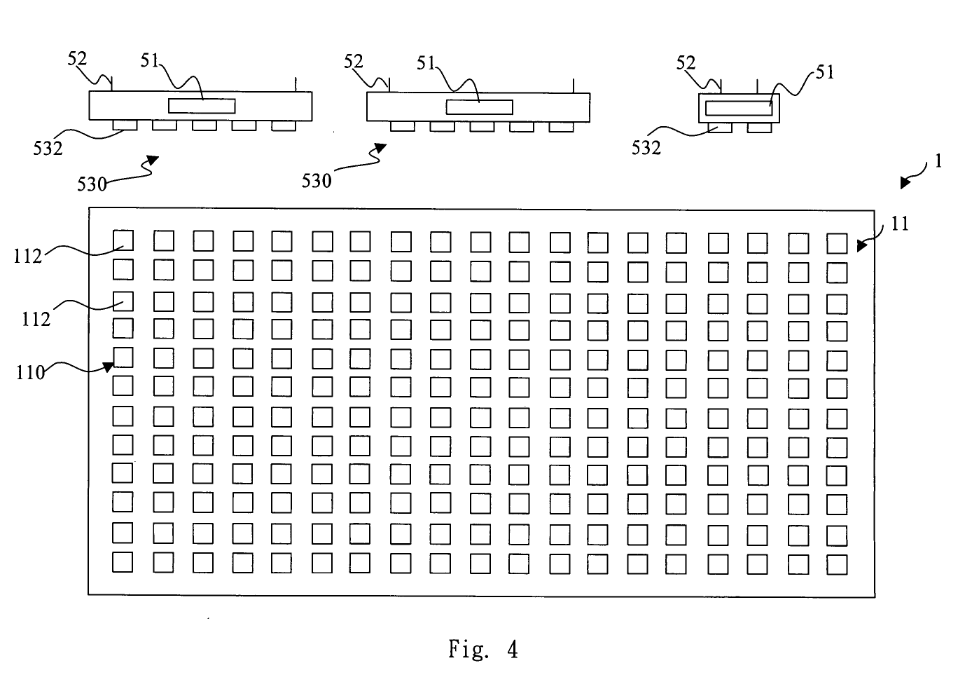

The platform 1 is approximate to the circuit board 4 and a surface of the platform 1 that faces a surface of the circuit board 4 with the input pads 441, has a positioning mechanism 11 thereon. FIG. 3 is a schematic diagram of a positioning mechanism in one preferred embodiment of the present invention, and FIG. 4 is a schematic diagram of a positioning mechanism in another preferred embodiment of the present invention. The positioning mechanism 11 can be presented in many ways in the embodiments to provide each programming module 5 movable and to be disposed precisely on the platform 1 according to users' preference. The ways of the positioning mechanism 11 will be further introduced later.

Each of the programming modules 5 being moved on the platform 1 is for disposing on a right position for contacting the input portions 44 and transmitting the programming codes to the chipsets 41 or the connecting jack 42. Each programming module 5 has a first connector 51 electrically connected the IC programming burner 2 and a number of output pins 52 extending towards the circuit board 4. Since the deployment of the output pins 52 of each programming modules 5 matches the deployment of the input pads 441 of the corresponding input portion 44, each of the output pins 52 is able to correspond to one of the input pads 441, so that the output pins 52 can be electrically connected the corresponding input pad 441 as they are individually in contact with their corresponding input pad 441.

The IC programming burner 2 has a number of second connectors 21 disposed on a side of the IC programming burner 2. A cable wire 22 can electrically connect each second connector 21 to the first connector 51. Alternatively, each second connector 21 can skip over the programming module 5 to be electrically connected with the connecting jack 42 directly with a cable wire (not shown in illustration). The IC programming burner 2 retrieves sets of programming codes that are separately based on the characteristics and formats of each chipset 41,43 and stored in the computer device 3.

While the computer device 3 starts to program codes to the chipsets 41,43, the computer device 3 first either moves the platform 1 to approach the circuit board 4 or moves the circuit board 4 to approach the platform 1 to bring each input pad 441 into contact with its corresponding output pin 52. Then, the computer device 3 detects whether each output pin 52 of at least one programming module 5 is correctly in contact with the corresponding input pad 441. After the computer device 3 detects that each output pin 52 of at least one programming module 5 is correctly in contact with the corresponding input pad 441, the computer device 3 sends a predetermined set of programming codes to the IC programming burner 2 in the order of the sequence of the second connectors 21 connected the programming module 5. Then, the IC programming burner 2 separately distributes the set of programming codes into each chipset 41 or connecting the jack 42 via the output pins 52 and the corresponding input pads 441. Finally, when the chipset 41 receives the set of programming codes from its input pads 441, or the chipset 43 receives the set of programming codes from the connecting jack 42, the computer device 3 completes to program codes to the chipsets 41, 43.

Referring to FIGS. 3 and 4 again, the positioning mechanism 11 that has been mentioned above, presents a plurality of first fastening portions 110 aligned equidistantly in a matrix arrangement on the platform 1, while the programming module 5 has at least a second fastening portion 532 configured on a side thereof and each of the second fastening portions 532 fits each of the first fastening portions 110. In the embodiment, each of the first fastening portions 110 can be an aperture 111 (or rod) and each of the second fastening portions 530 can be a rod 531 (or aperture) capable of plugging into the aperture 111. Or in another embodiment, each of the first fastening portions 110 can be such a metal plate 112 and each of the second fastening portions 530 can be a magnet 532 which is capable of being magnetized on the metal plate 112. Therefore, users can position a programming module 5 on the platform 1 and enable each output pin 52 to face the corresponding input pad 441 on his/her own willing by connecting the first fastening portion 110 and the second fastening portion 530 with each other.

Furthermore, the position of each first fastening portion 110 on the platform 1 is seen as a coordinate of the platform, therefore, in beginning the users can obtain the coordinate of the input portion 44 on the platform 1 in advance. Then, The users position the programming module 5 on the platform 1 according to the coordinate of the input portion 44. Because the deployment of the output pins 52 of the programming modules 5 matches the deployment of the input pads 441 of the corresponding input portion 44, each of the output pins 52 is able to contact the corresponding input pad 441 when the circuit board 4 and the platform 1 are in contact with each other. Therefore, the programming module 5 can be securely and precisely positioned on the platform 1 corresponding to the input portion 44 and enables each output pin 52 to face the corresponding input pad 441.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A machine for programming on-board chipsets, the machine comprising:
a circuit board having at least a chipset and a plurality of input pads electrically connected to the chipset individually;
a platform disposed approximately to the circuit board and facing to a surface of the circuit board having the input pads;
at least a programming module disposed movably on the platform, having a plurality of output pins extending towards the circuit board, wherein each of the output pins corresponds to one of the input pads to electrically connect the corresponding input pad to the corresponding input pad; and
an IC programming burner electrically connected to each programming module, and separately distributing a set of programming codes into each chipset via the output pins of each programming module and the corresponding input pads when the output pins electrically connect to the corresponding input pads respectively.

2. The machine of claim 1, wherein the platform has a positioning mechanism that provides each programming module being movable and positioned on the platform to face the corresponding input pad by each output pin.

3. The machine of claim 2, wherein the positioning mechanism is a plurality of first fastening portions which are aligned equidistantly in a matrix arrangement on the platform; and
the programming module has at least one second fastening portion fitting each of the first fastening portions to position the platform and enable each output pin to face the corresponding input pad when the second fastening portion is connected to the first fastening portion.

4. The machine of claim 3, wherein each of the first fastening portions is an aperture; and each of the second fastening portions is a rod suitable to plug into the aperture.

5. The machine of claim 3, wherein each of the first fastening portions is a metal plate; and each of the second fastening portions is a magnet capable of being magnetized on the metal plate.

6. The machine of claim 1, wherein each programming module further has a first connector, the IC programming burner has a plurality of second connectors, and each first connector is electrically connected to one of the second connectors by a cable wire.

7. The machine of claim 6 further comprises a computer device electrically connected to the IC programming burner, wherein the computer device stores a plurality of sets of programming codes and sends a predetermined set of programming codes to the IC programming burner according to the order in sequence of the second connectors.

8. The machine of claim 1, wherein the circuit board further comprises a connecting jack electrically connecting the chipset to the input pads.

9. A machine for programming on-board chipsets, which implements on a code programming process for at least one chipset mounted on a circuit board, and the circuit board has a plurality of input pads electrically connected to the chipset individually for transferring a set of programming codes into the chipset, the machine comprising:
a platform facing a surface of the circuit board having the input pads;
a plurality of programming modules disposed movably on the platform, separately having a plurality of output pins extending outwardly, wherein each of the output pins electrically connects an input pad when the output pins are in contact with their corresponding input pad 441
an IC programming burner electrically connected to each of the programming modules, and separately distributing a set of programming codes into each programming module when the output pins are electrically connected to the input pads.

10. The machine of claim 9, wherein the platform is configured a positioning mechanism that provides each programming module movable disposed on the platform facing the corresponding input pad by each output pin.

11. The machine of claim 10, wherein the positioning mechanism are a plurality of first fastening portions which are aligned equidistantly as a matrix arrangement on the platform; and
the programming module has at least a second fastening portion fitting each of the first fastening portions for positioning on the platform and enables each output pin to face the corresponding input pad when the second fastening portion is connected to the first fastening portion.

12. The machine of claim 10, wherein each of the first fastening portions is an aperture; and each of the second fastening portions is a rod capable of plugging into the aperture.

13. The machine of claim 10, wherein each of the first fastening portions is a metal plate; and each of the second fastening portions is a magnet capable of being magnetized on the metal plate.

14. The machine of claim 9, wherein each programming module has a first connector, the IC programming burner has a plurality of second connectors, and each first connector is electrically connected to one of the second connectors by a cable wire.

15. The machine of claim 14 further comprises a computer device electrically connected to the IC programming burner, wherein the computer device stores a plurality of sets of programming codes and sends a predetermined set of programming codes to the IC programming burner according to the order in sequence of the second connectors.
